(19) United States
(12) Patent Application Publication
(10) Pub. No.: US 2025/0341859 A1
(43) Pub. Date: Nov. 6, 2025

(54) DISPLAY MODULE AND DISPLAY DEVICE

(71) Applicant: Wuhan China Star Optoelectronics Semiconductor Display Technology Co., Ltd., Wuhan, Hubei (CN)

(72) Inventor: Wenqiang WANG, Wuhan, Hubei (CN)

(21) Appl. No.: 18/562,850

(22) PCT Filed: Jun. 29, 2023
(86) PCT No.: PCT/CN2023/103948

§ 371 Date: Jun. 3, 2025

(30) Foreign Application Priority Data
Nov. 14, 2022 (CN) 202211419729.3

(51) Int. Cl. G06F 1/16

(52) U.S. Cl. CPC G06F 1/1618; G06F 1/1641; G06F 1/1652

(57) ABSTRACT

A display module and a display device are provided; and the display module includes a display panel and at least one adhesive layer. The display panel includes a display function portion, a bonding portion and a bending portion. The display module includes a display region and a first frame region. The at least one adhesive layer includes a first sub-portion and a second sub-portion. The first sub-portion is in the first frame region, and the second sub-portion is in the display region and the first frame region. The first sub-portion has an elastic modulus greater than the second sub-portion.

### TECHNICAL FIELD

The present application relates to the field of display, and more particularly, to a display module and a display device.

### BACKGROUND

In recent years, the display module with the narrow frame is more and more popular by consumers. Referring to FIG. 1, in order to reduce the width of the frame of the display module 1, the bonding portion of the display panel 2 is bent toward the back of the display panel, and the display panel 2 includes a main body and base film layers, such as a substrate 37 and a buffer insulating layer 36, which are located on a side of the main body which is away from the light-emitting side of the display panel. In the FIG. 1, a metal wire layer 35, an interlayer insulating layer 34, a planarization layer 33, a touch control layer 32, and an organic passivation layer 31 are also shown. Because the bending portion in the bending region and the bonding portion are thin and the bending portion and the bonding portion are in a fixed state after they are bent, the base film layers apply a reverse acting stress on the encapsulation layer or the metal wire layer 35 of the display panel 2 during the bending, so that the encapsulation layer fractures or the metal wire layer 35 fractures in the vicinity of the lower frame of the display module 1. This results in abnormal display and intrusion of water and oxygen, thereby affecting the display effect.

Therefore, there is a need for a display module and a display device to solve the above-mentioned technical problems.

### SUMMARY

The present application provides a display module and a display device, which can alleviate the technical problem of the abnormal state of film layers in the vicinity of a lower frame of the display module.

To solve the above problems, the present application provides the following technical solutions:

The present application provides a display module including:
a display panel comprising a display function portion; a bonding portion disposed opposite to the display function portion; and a bending portion connecting the display function portion and the bonding portion;
at least one adhesive layer disposed on a side of the display function portion which is adjacent to the bonding portion;
in which the display module includes a display region corresponding to the display function portion and a first frame region located between the display region and the bending portion, the at least one adhesive layer includes a first sub-portion and a second sub-portion, the first sub-portion is located in the first frame region, the second sub-portion is located in the display region and the first frame region, and the first sub-portion has an elastic modulus greater than the second sub-portion.

In some embodiments, the first sub-portion and the second sub-portion are provided separately, and the adhesive layer is provided with a gap portion between the first sub-portion and the second sub-portion.

In some embodiments, the display module further includes a shielding portion located on a side of the display function portion which is away from the bonding portion; in which an orthographic projection of the gap portion on the display function portion is located within the orthographic projection of the shielding portion on the display function portion.

In some embodiments, the gap portion is located in the first frame region.

In some embodiments, the display module includes a first adhesive layer disposed at a side of the display function portion which is adjacent to the bonding portion, a first backplane layer disposed at a side of the first adhesive layer which is away from the display function portion, a second adhesive layer disposed at a side of the first backplane layer which is away from the display function portion, a light-shielding buffer layer disposed at a side of the second adhesive layer which is away from the display function portion, a third adhesive layer disposed at a side of the light-shielding buffer layer which is away from the display function portion, and a support function layer disposed at a side of the third adhesive layer which is away from the display function portion; in which the elastic modulus of the first sub-portion of the first adhesive layer is greater than the elastic modulus of the first sub-portion of the second adhesive layer, and the elastic modulus of the first sub-portion of the second adhesive layer is greater than the elastic modulus of the first sub-portion of the third adhesive layer.

In some embodiments, a thickness of the first sub-portion of the first adhesive layer is greater than a thickness of the first sub-portion of the second adhesive layer, and a thickness of the first sub-portion of the second adhesive layer is greater than a thickness of the first sub-portion of the third adhesive layer; a sum of the thickness of the first sub-portion of the first adhesive layer, the thickness of the first sub-portion of the second adhesive layer, and the thickness of the first sub-portion of the third adhesive layer is equal to a sum of a thickness of the second sub-portion of the first adhesive layer, a thickness of the second sub-portion of the second adhesive layer, and a thickness of the second sub-portion of the third adhesive layer.

In some embodiments, the first sub-portion of the first adhesive layer includes a first end portion away from the display region, and the first end portion protrudes from a corresponding end portion of the first backplane layer; an orthographic projection of the first sub-portion of the second adhesive layer on the first backplane layer is located within the first backplane layer, and an orthographic projection of the first sub-portion of the second adhesive layer on the light-shielding buffer layer is located within the light-shielding buffer layer; an orthographic projection of the first sub-portion of the third adhesive layer on the light-shielding buffer layer is located within the light-shielding buffer layer, and an orthographic projection of the first sub-portion of the second adhesive layer on the support functional layer is located within the support functional layer.

In some embodiments, the first adhesive layer is provided with a first gap sub-portion between a corresponding first sub-portion and a corresponding second sub-portion, the second adhesive layer is provided with a second gap sub-portion between a corresponding first sub-portion and a corresponding second sub-portion, and the third adhesive layer is provided with a third gap sub-portion between a corresponding first sub-portion and a corresponding second sub-portion; wherein a width of the first gap sub-portion is greater than or equal to a width of the second gap sub-portion, and a width of the second gap sub-portion is greater than or equal to a width of the third gap sub-portion.

In some embodiments, an orthographic projection of the first gap sub-portion on the display function portion, an orthographic projection of the second gap sub-portion on the display function portion, and an orthographic projection of the third gap sub-portion on the display function portion are overlapped.

In some embodiments, a bending radius of the first adhesive layer is less than a bending radius of the second adhesive layer, and a bending radius of the second adhesive layer is less than a bending radius of the third adhesive layer.

In some embodiments, the display module further includes a polarizing layer located on a side of the display function portion which is away from the bonding portion; in which the polarizing layer is located within the display region and the first frame region, and an orthographic projection of the polarizing layer on the display function portion overlaps with an orthographic projection of the first sub-portion of the at least one adhesive layer on the display function portion.

In some embodiments, the display module further includes a protective layer on a side of the bending portion which is away from the display region, and on a side of the display function portion which is away from the bonding portion; in which an end portion of the protective layer which is adjacent to one side of the polarizing layer is provided in the first frame region, and the protective layer and the polarizing layer are provided at an interval.

In some embodiments, the display module further includes an ultra-thin glass on a side of the polarizing layer which is away from the display function portion, and a window cover plate on a side of the ultra-thin glass which is away from the display function portion.

In some embodiments, a width of the gap portion of the adhesive layer is a first width in a direction from the bending portion to a center of the display function portion;
a thickness between a surface of a side, which is away from the window cover plate, of the support function layer and a surface of a side, which is away from the support function layer, of the window cover plate is a first thickness;
in which the first width is 50% to 150% of the first thickness.

In some embodiments, the elastic modulus of the first sub-portion is greater than or equal to 20 Mpa.

In some embodiments, a material of the first sub-portion is a pressure-sensitive adhesive and a material of the second sub-portion is an optical adhesive.

The present application further provides a display device comprising a display module and a main body, the display module being integrated with the main body;
the display module including:
a display panel comprising a display function portion, a bonding portion disposed opposite to the display function portion, and a bending portion connecting the display function portion and the bonding portion;
at least one adhesive layer disposed on a side of the display function portion which is adjacent to the bonding portion;
in which the display module includes a display region corresponding to the display function portion and a first frame region located between the display region and the bending portion, the at least one adhesive layer includes a first sub-portion and a second sub-portion, the first sub-portion is located in the first frame region, the second sub-portion is located in the display region and the first frame region, and the first sub-portion has an elastic modulus greater than the second sub-portion.

In some embodiments, the first sub-portion and the second sub-portion are provided separately, and the adhesive layer is provided with a gap portion between the first sub-portion and the second sub-portion.

In some embodiments, the display module includes a first adhesive layer disposed on a side of the display function portion which is adjacent to the bonding portion, a first backplane layer disposed on a side of the first adhesive layer which is away from the display function portion, a second adhesive layer disposed on a side of the first backplane layer which is away from the display function portion, a light-shielding buffer layer disposed on a side of the second adhesive layer which is away from the display function portion, a third adhesive layer disposed on a side of the light-shielding buffer layer which is away from the display function portion, and a support function layer disposed at a side of the third adhesive layer which is away from the display function portion;
in which the elastic modulus of the first sub-portion of the first adhesive layer is greater than the elastic modulus of the first sub-portion of the second adhesive layer, and the elastic modulus of the first sub-portion of the second adhesive layer is greater than the elastic modulus of the first sub-portion of the third adhesive layer.

In some embodiments, the display module further includes a polarizing layer located on a side of the display function portion which is away from the bonding portion;
in which the polarizing layer is located within the display region and the first frame region, and an orthographic projection of the polarizing layer on the display function portion overlaps with an orthographic projection of the first sub-portion of the at least one adhesive layer on the display function portion.

### BENEFICIAL EFFECT

The present application has the advantageous effect: the rigidity of the lower frame region of the display module is increased, by reinforcing the adhesive layer which is easy to increase the elastic modulus, as well as setting the elastic modulus of a first sub-portion of the adhesive layer corresponding to the first frame region to be greater than the elastic modulus of a second sub-portion of the corresponding display region. In the bending process, the high elastic modulus of the first sub-portion is used to reduce the reverse acting force of the base film layer far away from the light-emitting side on the film layer of the display panel, thereby reducing the risk of fracture and failure of the film layer at the lower frame and improving the display effect.

### BRIEF DESCRIPTION OF THE DRAWINGS

FIG. 1 is a schematic structural diagram showing fracture of a film layer of a display module;

FIG. 2 is a first structural diagram of a display module according to an embodiment of the present application;

FIG. 3 is a second structural diagram of a display module according to an embodiment of the present application;

FIG. 4 is a bending simulation simulation diagram of a display module according to an embodiment of the present application;

FIG. 5 is a bending simulation comparison diagram of a display module according to an embodiment of the present application;

FIG. 6 is a diagram showing comparative and experimental characterization of a display module according to an embodiment of the present application;

FIG. 7 is another diagram showing comparative and experimental characterization of a display module according to an embodiment of the present application;

FIG. 8 is a schematic structural diagram of a display device according to an embodiment of the present application.

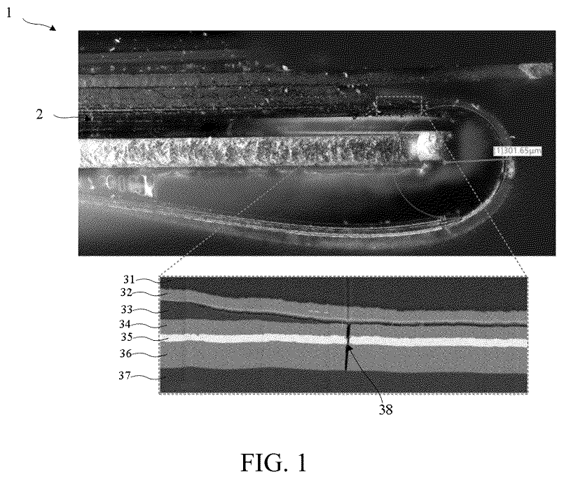

### DETAILED DESCRIPTION

The present application provides a display module and a display device. To make the object, the technical solution and the effect of the present application clearer and more definite, the present application will be described in further detail below with reference to the accompanying drawings and examples. It is to be understood that the specific embodiments described herein are merely illustrative of the present application and are not intended to limit the present application.

The embodiments of the present application provides a display module and a display device. Detailed descriptions are given below. It should be noted that the order in which the following examples are described is not intended to limit the preferred order of the examples.

In recent years, the display module with a narrow frame is more and more popular by consumers. In order to reduce the width of the frame of the display module, the bonding portion of the display panel is bent toward the back of the display panel, and the display panel includes a main body and a buffer layer located on the side of the main body which is away from the light-emitting side. Since the bonding portion and the bending portion in the bending region are thin and are in a fixed state after the bending, the buffer layer applies a reverse acting stress to the encapsulation layer or the wiring layer of the display panel during the bending process, so that the encapsulation layer fractures or the metal wiring film layer fractures in the vicinity of the lower frame of the display module. This results in water-oxygen intrusion and display abnormality, thereby affecting the display effect.

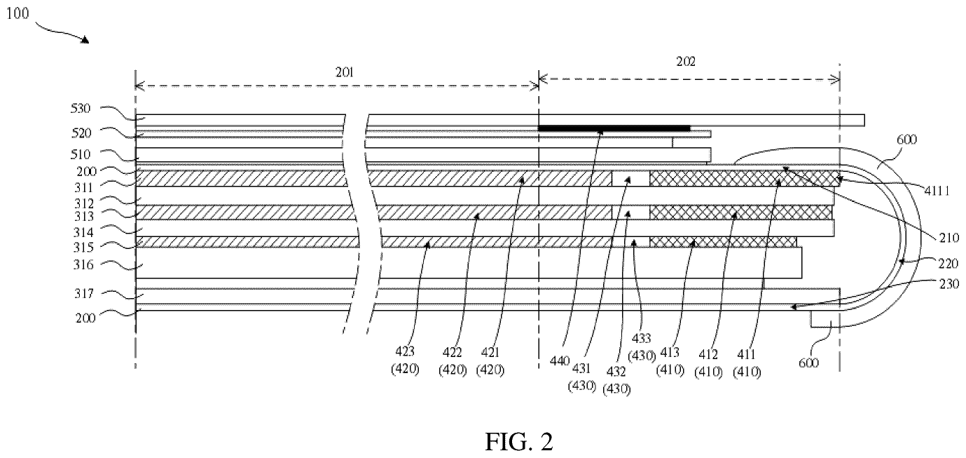

Referring to FIGS. 2-7, an embodiment of the present application provides a display module 100 including:
a display panel 200 including a display function portion 210, a bonding portion 230 disposed opposite to the display function portion 210, and a bending portion 220 connecting the display function portion 210 and the bonding portion 230;
at least one adhesive layer provided on one side of the display panel 200;
in which the display module 100 includes a display region 201 corresponding to the display function portion 210 and a first frame region 202 located on a side of the display region 201 which is adjacent to the bending portion 220, the at least one adhesive layer includes a first sub-portion 410 located in the first frame region 202 and a second sub-portion 420 located in the display region 201 and the first frame region 202, and the elastic modulus of the first sub-portion 410 is greater than that of the second sub-portion 420.

According to the present application, the adhesive layer which is easy to increase the elastic modulus is reinforced, and the elastic modulus of the first sub-portion of the bonding layer corresponding to the first frame region is set to be larger than the elastic modulus of the second sub-portion corresponding to the display region, so that the rigidity of the lower frame region of the display module is improved. In the bending process, the high elastic modulus of the first sub-portion is used to reduce the reverse acting force of the base film layer far away from the light-emitting side on the film layer of the display panel, thereby reducing the risk of fracture and failure of the film layer at the lower frame and improving the display effect.

The technical solution of the present application will now be described with reference to specific embodiments.

In the present embodiment, referring to FIG. 2, the display module 100 includes a display panel 200 and at least one adhesive layer disposed on one side of the display panel 200. The display panel 200 includes a display function portion 210, a bonding portion 230 disposed opposite to the display function portion 210, and a bending portion 220 connecting the display function portion 210 and the bonding portion 230. The display module 100 includes a display region 201 corresponding to the display function portion 210 and a first frame region 202 located on the side of the display region 201 which is adjacent to the bending portion 220. The first frame region 202 is a lower frame region of the display module 100. At least one adhesive layer includes a first sub-portion 410 and a second sub-portion 420. The first sub-portion 410 is located in the first frame region 202, the second sub-portion 420 is located in the display region 201 and the first frame region 202, and the elastic modulus of the first sub-portion 410 is greater than that of the second sub-portion 420.

In some embodiments, the display region 201 of the display function portion 210 assumes a display function, and the first frame region 202 of the display function portion 210 does not assume a display function.

In some embodiments, referring to FIG. 2, the display module 100 includes a first adhesive layer 311 disposed at a side of the display function portion 210 which is adjacent to the bonding portion 230, a first backplane layer 312 disposed at a side of the first adhesive layer 311 which is away from the display function portion 210, a second adhesive layer 313 disposed at a side of the first backplane layer 312 which is away from the display function portion 210, a light-shielding buffer layer 314 disposed at a side of the second adhesive layer 313 which is away from the display function portion 210, a third adhesive layer 315 disposed at a side of the light-shielding buffer layer 314 which is away from the display function portion 210, and a support function layer 316 disposed at a side of the third adhesive layer 315 which is away from the display function portion 210.

In some embodiments, the material of the light-shielding buffer layer 314 may include a light-shielding material and a buffer material, which may be foam.

In some embodiments, the display module further includes a second backplane layer 317 located between the support function layer 316 and the bonding portion 230.

For ease of description, referring to FIG. 2, the following adhesive layer will be described with reference to the first adhesive layer 311 as an example.

The main body of the panel includes a driving line layer, a light-emitting layer, and an encapsulation layer. The encapsulation layer includes a first inorganic layer, a second inorganic layer, and an organic layer located between the first inorganic layer and the second inorganic layer. The first inorganic layer is located on a side of the driving line layer away from the first adhesive layer 311, and the driving line layer includes a metal wiring layer. During bending of the bending portion and the bonding portion, simulation results show that a position occurring a main failure risk of the main body is located at an end of the inorganic layer of the encapsulation layer. And, the position deformation is maximum, and the position deformation is directly related to the rigidity of the film layer of the first frame region 202 of the display module 100.

The material of the first backplane layer 312 is generally polyethylene terephthalate or polyimide, the material of the light-shielding buffer layer 314 is generally black polyimide, and the material of the support functional layer 316 is generally steel. The material of the adhesive layer is generally an optical adhesive or a pressure sensitive adhesive. The adhesive layer is more susceptible to changes in elastic modulus, compared with the first backplane and the light-shielding buffer layer 314. The adhesive layer is closer to the display panel 200 than the supporting functional layer 316. When the display panel 200 is bent, the adhesive layer acts more directly on the reinforcing effect of the display panel 200.

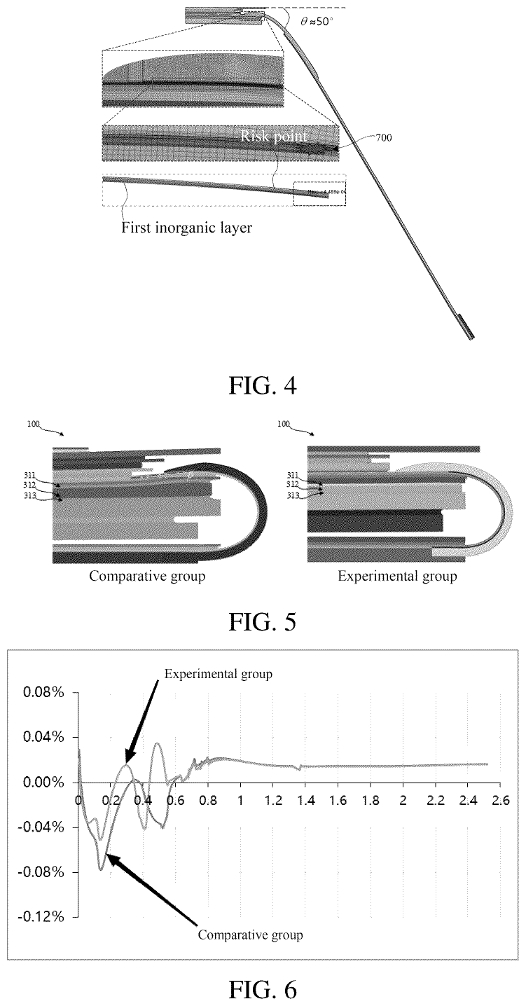

Providing an experimental group and a comparative group, the experimental group is conducted under following conditions: the elastic modulus of the first sub-portion 410 is greater than the elastic modulus of the second sub-portion 420, the elastic modulus of the first sub-portion 410 is 20 Mpa, and the elastic modulus of the second sub-portion 420 is 3 Mpa. The comparative group is conducted under following conditions: the elastic modulus of the entire adhesive layer was consistent, and the elastic modulus of each of the adhesive layers was 3 MPa. The measurement for failure strain and position parameters of the display panel 200 is performed during bending and in the final state of bending, and the parameters are measured and plotted as follows. The vertical coordinate denotes the failure strain of the first inorganic layer; the horizontal coordinate denotes a distance (the unit thereof is millimeters) between the measurement point and the end of the first inorganic layer which is away from the center of the display panel 200, and the measurement origin point 700 is shown in FIG. 4.

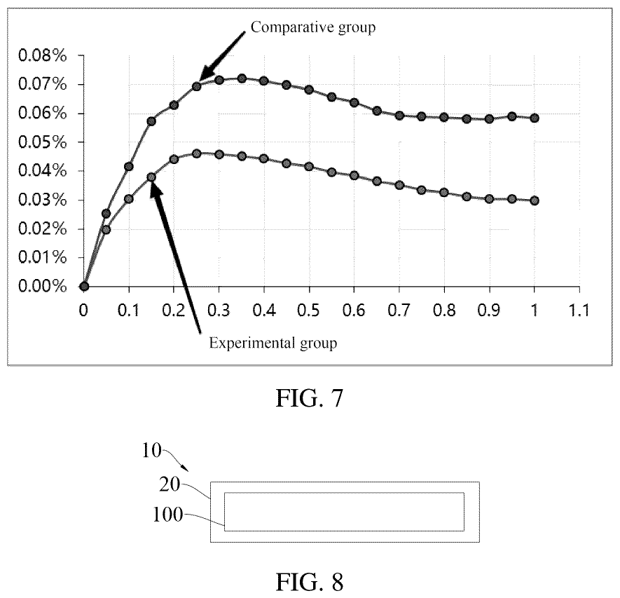

Through simulation comparison, it is found that the elastic modulus of the first sub-portion 410 is larger than that of the second sub-portion 420 by adopting the superposition of the present application. Referring to FIG. 5, the degree of the warping of the first adhesive layer 311, the second adhesive layer 313, and the first backplane layer 312 in the experimental group is significantly reduced. Referring to FIGS. 6 and 7, it is shown that the stress of the first inorganic layer of the display module 100 is significantly reduced during bending and in the final state, which indicates that the risk of failure and fracture is effectively improved.

The adhesive layer which is easy to increase the elastic modulus is reinforced, and the elastic modulus of the adhesive layer corresponding to the first sub-portion of the first frame region is set to be larger than the elastic modulus of the second sub-portion of the corresponding display region, so that the rigidity of the lower frame region of the display module 100 is improved. In the bending process, it can reduce the reveres acting force exerted on the metal wire film layer or the encapsulation layer of the display panel 200 by the base film layer, such as the substrate or the buffer insulating layer, far away from the light-emitting side, thereby reducing the risk of fracture and failure of the film layer and improving the display effect.

In some embodiments, referring to FIG. 2, the first sub-portion 410 and the second sub-portion 420 are disposed separately. The adhesive layer is provided with a gap portion 430 between the first sub-portion 410 and the second sub-portion 420, and the display module 100 may be a folding display module 100. During folding of the display panel 200, the adhesive layer slides with respect to an adjacent film layer due to bending, thereby resulting in a film layer displacement. The gap portion 430 may accommodate the adhesive layer that is displaced, thereby avoiding a risk of peeling of the adhesive layer from the adjacent film layer due to the film layer displacement.

In some embodiments, referring to FIG. 2, the display module 100 further includes a shielding portion 440 located on a side of the display function portion 210 away from the bonding portion 230. The adhesive layer includes a gap portion 430 between the first sub-portion 410 and the second sub-portion 420. The orthographic projection of the gap portion 430 on the display function portion 210 is located within the orthographic projection of the shielding portion 440 on the display function portion 210.

The gap portion 430 is shielded by the shielding portion 440 to improve the front observation feeling on the display module 100. The material of the shielding portion 440 may be a light-shielding material such as black ink, and is not specifically limited herein.

In some embodiments, referring to FIG. 2, the gap portion 430 is located within the first frame region 202. The gap portion 430 is used for accommodating the displaced adhesive layer, thereby restricting the position of displacement in the first frame region 202, reducing the influence on the normal display region 201, and ensuring the display quality.

In some embodiments, a width of the gap portion 430 is a first width in a direction from the bending portion 220 to a center of the display function portion 210. The thickness between the surface of one side, which is away from the window cover plate 530, of the support function layer 316 and the surface of one side, which is away from the support function layer 316, of the window cover plate 530 is a first thickness. The first width is 50% to 150% of the first thickness.

If the display module is a folding display module, the display module is formed by stacking a multilayer film layer and an adhesive layer. After folding and bending, the end portions of the display module are subjected to cumulative shear deformation due to shear stress between the film layers. Therefore, the end portions of the display module are subjected to interlayer displacement, and the magnitude of the interlayer displacement is directly related to the material of the film layer, the thickness of the adhesive layer, the thickness of the display module, and the elastic modulus. The smaller the elastic modulus of the adhesive layer, the larger the displacement value. The larger the elastic modulus of the display panel, and the larger the displacement value. The greater the thickness of the display panel, the greater the displacement value of the end portion. The smaller the folded bending radius of the display module, the larger the displacement value of the end portion. In a high temperature environment, the elastic modulus of the adhesive layer is decreased, deformation is more easily generated, and the total displacement is larger. Therefore, the thickness data of the display module, which is easily measured in the actual manufacturing process, is selected to define the width of the gap portion 430.

In the figures, for convenience of drawing, the ratio of the thickness of the display panel 200 to the width of the gap portion 430 is shown only. For details, reference is made to a numerical ratio, and the setting width of the gap portion 430 is related to the first thickness. Before and after the folding of the display module 100, the displacement distance of the film layer of the display panel 200 is 50% to 150% of the first thickness, and the width of the gap portion 430 is set to 50% to 150% of the first thickness, so that the displaced adhesive layer can be effectively accommodated, and the risk of peeling the adhesive layer from the adjacent film layer due to film layer displacement is avoided.

In some embodiments, the first thickness is 0.4 mm to 0.8 mm, preferably the first width of the gap portion 430 is 0.4 mm to 0.7 mm. As a result, the width of the gap portion 430 can be reduced while the folded and displaced film layer can be ensured to be accommodated. And, a larger setting region of the first sub-portion 410 can be ensured, the reverse acting force of the base film layer away from the light-emitting side on the film layer of the display panel 200 can be effectively reduced, thereby reducing the risk of fracture and failure of the film layer, and improving the display effect.

In some embodiments, referring to FIG. 2, the display module 100 includes a first adhesive layer 311 disposed at a side of the display function portion 210 adjacent to the bonding portion 230, a first backplane layer 312 disposed at a side of the first adhesive layer 311 away from the display function portion 210, a second adhesive layer 313 disposed at a side of the first backplane layer 312 away from the display function portion 210, a light-shielding buffer layer 314 disposed at a side of the second adhesive layer 313 away from the display function portion 210, a third adhesive layer 315 disposed at a side of the light-shielding buffer layer 314 away from the display function portion 210, and a support function layer 316 disposed at a side of the third adhesive layer 315 away from the display function portion 210. The elastic modulus of the first sub-portion 411 (410) of the first adhesive layer 311 is greater than the elastic modulus of the second sub-portion 421 (420) of the first adhesive layer 311, the elastic modulus of the first sub-portion 412 (410) of the second adhesive layer 313 is greater than the elastic modulus of the second sub-portion 422 (420) of the second adhesive layer 313, and the elastic modulus of the first sub-portion 413 (410) of the third adhesive layer 315 is greater than the elastic modulus of the second sub-portion 423 (420) of the third adhesive layer 315.

The multi-layer reinforcement is performed by using the multi-layer adhesive layer, so that the rigidity of the lower frame region of the display module 100 is further improved. In the bending process, the reverse acting force of the base film layer away from the light-emitting side on the film layer of the display panel 200 is reduced, thereby reducing the risk of fracture and failure of the film layer and improving the display effect.

In some embodiments, the elastic modulus of the first sub-portion 411 (410) of the first adhesive layer 311 is greater than the elastic modulus of the first sub-portion 412 (410) of the second adhesive layer 313, and the elastic modulus of the first sub-portion 412 (410) of the second adhesive layer 313 is greater than the elastic modulus of the first sub-portion 413 (410) of the third adhesive layer 315.

The first adhesive layer 311, the second adhesive layer 313, and the third adhesive layer 315 are closer to the display function portion 210 than the display function portion 210. The elastic modulus of the adhesive layer closer to the display function portion 210 is optimized. The larger the elastic modulus of the first sub-portion 410 corresponding to the adhesive layer is, the more directly the increased elastic modulus can be applied to the display panel 200. In the bending process, the reverse acting force exerted on the film layer of the display panel 200 by the base film layer away from the light-emitting side is reduced more directly, thereby reducing the risk of fracture and failure of the film layer and improving the display effect.

In some embodiments, referring to FIG. 2, the thickness of the first sub-portion 411 (410) of the first adhesive layer 311 is greater than the thickness of the first sub-portion 412 (410) of the second adhesive layer 313, and the thickness of the first sub-portion 412 (410) of the second adhesive layer 313 is greater than the thickness of the first sub-portion 413 (410) of the third adhesive layer 315. The sum of the thickness of the first sub-portion 411 (410) of the first adhesive layer 311, the thickness of the first sub-portion 412 (410) of the second adhesive layer 313, and the thickness of the first sub-portion 413 (410) of the third adhesive layer 315 is equal to the sum of the thickness of the second sub-portion 421 (420) of the first adhesive layer 311, the thickness of the second sub-portion 422 (420) of the second adhesive layer 313, and the thickness of the second sub-portion 423 (420) of the third adhesive layer 315.

The closer to the display panel 200, the thicker the first sub-portion 410 corresponding to the adhesive layer is. The greater the elastic modulus of the first sub-portion 410 corresponding to this adhesive layer is, the more directly the increased elastic modulus can be applied to the display panel 200. In the bending process, the reverse acting force exerted on the film layer of the display panel 200 by the base film layer away from the light-emitting side can be reduced more directly, thereby reducing the risk of fracture and failure of the film layer and improving the display effect. At the same time, the thickness of the three first sub-portions 410 is equal to the thickness of the corresponding three second sub-portions 420, so that the thickness of the corresponding adhesive layer in the first frame region 202 and the thickness of the corresponding adhesive layer in the display region 201 are kept unchanged. So, a segment difference is avoided, and the flatness of the film layer is ensured.

In some embodiments, referring to FIG. 2, the first sub-portion 411 (410) of the first adhesive layer 311 includes a first end 4111 away from the display region. The first end 4111 protrudes from a corresponding end of the first backplane layer 312. An orthographic projection of the first sub-portion 412 (410) of the second adhesive layer 313 on the first backplane layer 312 is located within the first backplane layer 312, and an orthographic projection of the first sub-portion 412 (410) of the second adhesive layer 313 on the light-shielding buffer layer 314 is located within the light-shielding buffer layer 314. An orthographic projection of the first sub-portion 413 (410) of the third adhesive layer 315 on the light-shielding buffer layer 314 is located within the light-shielding buffer layer 314, and an orthographic projection of the first sub-portion 412 (410) of the second adhesive layer 313 on the support functional layer 316 is located within the support functional layer 316.

The first end portion 4111 protrudes from the corresponding end of the first backplane layer 312, and the first adhesive layer 311 is used to support and cushion the display function portion 210 and the bending portion 220 of the display panel 200. When the bending portion 220 is bent, the bending stress of the bending portion 220 is cushioned to reduce bending damage to the bending portion 220.

The ends, which are away from the display region, of both first sub-portion 412 (410) of the second adhesive layer 313 and the first sub-portion 413 (410) of the third adhesive layer 315 are provided in a retractable manner, so that the risk of exposing the adhesive layer due to film layer displacement is reduced during the folding process of the display module, or the risk of exposing the adhesive layer due to tolerance is reduced during the manufacturing process.

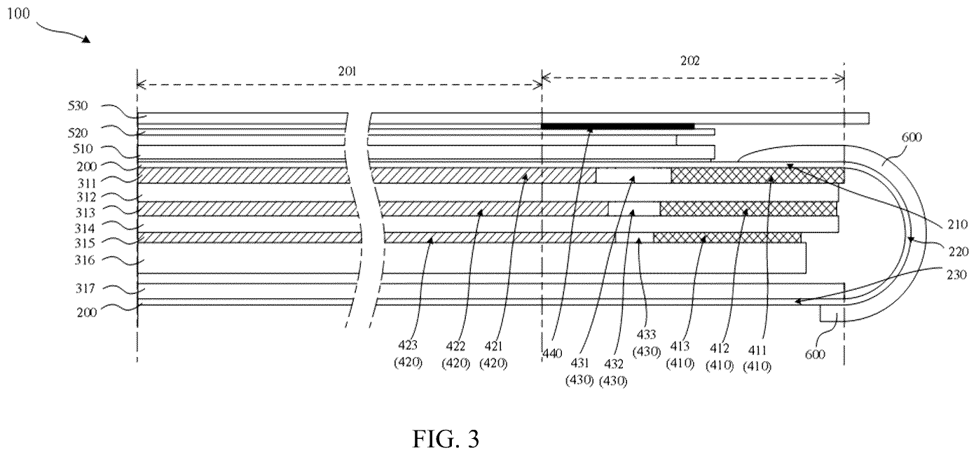

In some embodiments, referring to FIG. 3, the first adhesive layer 311 is provided with a first gap sub-portion 431 (430) between a corresponding first sub-portion 411 (410) and a corresponding second sub-portion 421 (420). The second adhesive layer 313 is provided with a second gap sub-portion 432 (430) between a corresponding first sub-portion 412 (410) and a corresponding second sub-portion 422 (420). The third adhesive layer is provided with a third gap sub-portion 433 (430) between a corresponding first sub-portion 413 (410) and a corresponding second sub-portion 423 (420). The width of the first gap sub-portion 431 (430) is greater than or equal to the width of the second gap sub-portion 432 (430), and the width of the second gap sub-portion 432 (430) is greater than or equal to the width of the third gap sub-portion 433 (430).

Generally, in order to protect the display panel 200, the display module 100 is folded inwards, so that the bending radius of the first adhesive layer 311 is smaller than the bending radius of the second adhesive layer 313, and the bending radius of the second adhesive layer 313 is smaller than the bending radius of the third adhesive layer 315. The smaller the bending radius or the thicker the thickness of the film layer, the larger the displacement amount of the film layer. And, the gap portion 430 includes the first gap sub-portion 431 (430), the second gap sub-portion 432 (430), and the third gap sub-portion 433 (430). Therefore, the size of the gap for accommodating the bended and displaced film layer is optimized, so that the displaced film layer is contained, the film layer is prevented from being pressed and deformed, and the display effect of the display module is ensured.

In some embodiments, the orthographic projection of the first gap sub-portion 431 (430) on the display function portion 210, the orthographic projection of the second gap sub-portion 432 (430) on the display function portion 210, and the orthographic projection of the third gap sub-portion 433 (430) on the display function portion 210 are overlapped.

The gap has an overlapping region, which facilitates release of the bending stress. And, the first sub-portion 410 having a relatively high elastic modulus is more concentrated, which facilitates centrally reinforcing the rigidity of the lower frame region of the display module 100. In the bending process, the reverse acting force of the base film layer away from the light-emitting side on the film layer of the display panel 200 is reduced, thereby reducing the risk of fracture and failure of the film layer and improving the display effect.

In some embodiments, referring to FIG. 2, the display module 100 further includes a polarizing layer 510 located on a side of the display function portion 210 away from the bonding portion 230. The polarizing layer 510 is located in the display region 201 and the first frame region 202, and the orthographic projection of the polarizing layer 510 on the display function portion 210 overlaps with the orthographic projection of the first sub-portion 410 of the at least one adhesive layer on the display function portion 210.

In the cross-sectional view, the polarizing layer 510 presses a part of the first sub-portion 410 to reduce a reverse acting force of the film layer between the polarizing layer 510 and the first sub-portion 410 on the display panel 200, and a part of the reverse acting force is applied to the polarizing layer 510, thereby reducing a risk of fracture and failure of the film layer and improving a display effect.

In some embodiments, referring to FIG. 2, the display module 100 further includes a protective layer 600 located on a side of the bending portion 220 away from the display region 201 and on a side of the display function portion 210 away from the bonding portion 230. The orthographic projection of the protective layer 600 on the display function portion 210 overlaps with the orthographic projection of the first sub-portion 410 of the at least one adhesive layer on the display function portion 210, and the protective layer 600 is provided at a distance from the polarizing layer 510.

The protective layer 600 is used to protect the bending portion 220 of the display panel 200. In the bending process of the bending portion 220, a direct traction force is applied to the display panel 200. In the cross-sectional view, the protective layer 600 presses a part of the first sub-portion 410 to reduce the reverse acting force of the film layer between the protective layer 600 and the first sub-portion 410 on the display panel 200, and a part of the reverse acting force is applied to the protective layer 600, thereby reducing the risk of fracture and failure of the film layer and improving the display effect. The protective layer 600 and the polarizing layer 510 are provided at an interval to reduce the risk of abutment and damage between the protective layer 600 and the polarizing layer 510 when the display module 100 is folded.

In some embodiments, the protective layer may be a protective material such as an ultraviolet curable adhesive.

In some embodiments, referring to FIG. 2, the display module 100 further includes a polarizing layer 510, an ultra-thin glass 520 on the side of the polarizing layer 510 away from the display function 210, and a window cover plate 530 on the side of the ultra-thin glass 520 away from the display function 210.

In some embodiments, the shielding portion 440 may be located between the ultra-thin glass 520 and the window cover plate 530.

In some embodiments, the elastic modulus of the first sub-portion 410 is greater than or equal to 20 Mpa.

Generally, the elastic modulus of the adhesive layer is 0.5 Mpa to 3 Mpa, and the elastic modulus has no significant effect on reducing the reverse acting force of the main body of the panel. Setting the elastic modulus of the first sub-portion 410 to be 20 Mpa or more can effectively reduce the reverse acting force of the base film layer away from the light-emitting side against the film layer of the display panel 200, thereby reducing the risk of fracture and failure of the film layer fracture, and improving the display effect.

In some embodiments, preferably, the elastic modulus of the first sub-portion 410 is from 20 Mpa to 50 Mpa. The first sub-portion 410 also needs to have a function of bonding. The greater the elastic modulus, the lower the bonding ability. Therefore, the elastic modulus of the first sub-portion 410 cannot be higher than 50 MPa.

In some embodiments, the first sub-portion 410 and the second sub-portion 420 may be of the same material, such as an optical adhesive or a pressure sensitive adhesive. At the time of fabrication, the elastic modulus is changed by different fabrication processes. For example, the larger the gas content at the time of fabrication, the smaller the elastic modulus of the material; or different additives are added to change the elastic modulus, so that the elastic modulus of the first sub-portion 410 is greater than the elastic modulus corresponding to the second sub-portion 420.

In some embodiments, the first sub-portion 410 and the second sub-portion 420 may be of different materials. For example, the first sub-portion 410 is a pressure sensitive adhesive, the second sub-portion 420 is an optical adhesive, and the elastic modulus of the pressure sensitive adhesive is generally greater than that of the optical adhesive, so as to achieve that the elastic modulus of the first sub-portion 410 is greater than that of the corresponding second sub-portion 420.

In some embodiments, the second sub-portion 420 is a transparent material, and the first sub-portion 410 is located in the non-display region 201 and may be a transparent material or an opaque material, which is not specifically limited herein.

According to the present application, the elastic modulus of the first sub-portion of the bonding layer corresponding to the first frame region is set to be larger than the elastic modulus of the second sub-portion corresponding to the display region, so that the rigidity of the lower frame region of the display module is improved. In the bending process, the high elastic modulus of the first sub-portion is used to reduce the reverse acting force of the base film layer away from the light-emitting side on the film layer of the display panel, thereby reducing the risk of fracture and failure of the film layer of the lower frame and improving the display effect.

Referring to FIG. 8, an embodiment of the present application further provides a display device 10 including a display module 100 as described above and a main body 20. The display module 100 is integrated with the main body 20.

For the specific structure of the display module 100, any one of the above-described embodiments of the display module 100 and the accompanying drawings are referred, and details are not described herein.

In this embodiment, the main body 20 may include a middle frame, a frame glue, an external hanging element, and the like. The display device 10 may be a display terminal such as a mobile phone, a tablet, or a television, which is not limited herein.

An embodiment of the present application discloses a display module and a display device. The display module includes a display panel and at least one adhesive layer. The display panel includes a display function portion, a bonding portion and a bending portion. The display module includes a display region and a first frame region. The at least one adhesive layer includes a first sub-portion and a second sub-portion. The first sub-portion is located in the first frame region, the second sub-portion is located in the display region and the first frame region, and the elastic modulus of the first sub-portion is larger than that of the second sub-portion. According to the present application, an adhesive layer which is easy to increase the elastic modulus is reinforced, and the elastic modulus of the first sub-portion of the adhesive layer corresponding to the first frame region is set to be larger than the elastic modulus of the second sub-portion corresponding to the display region, so that the rigidity of the lower frame region of the display module is improved. In the bending process, the reverse acting force of the base film layer away from the light-emitting side on the film layer of the display panel is reduced, thereby reducing the risk of fracture and failure of the film layer of the lower frame, and improving the display effect.

It will be appreciated by those of ordinary skill in the art that equivalents may be substituted or altered in accordance with the technical solution of the present application and its inventive concept, and all such variations or substitutions are intended to fall within the scope of the claims appended hereto.

1. A display module, comprising:
a display panel comprising a display function portion; a bonding portion disposed opposite to the display function portion; and a bending portion connecting the display function portion and the bonding portion; and
at least one adhesive layer disposed on a side of the display function portion which is adjacent to the bonding portion;
wherein the display module comprises a display region corresponding to the display function portion and a first frame region located between the display region and the bending portion, the at least one adhesive layer comprises a first sub-portion and a second sub-portion, the first sub-portion is located in the first frame region, the second sub-portion is located in the display region and the first frame region, and the first sub-portion has an elastic modulus greater than the second sub-portion.

2. The display module according to claim 1, wherein the first sub-portion and the second sub-portion are provided separately, and the at least one adhesive layer is provided with a gap portion between the first sub-portion and the second sub-portion.

3. The display module according to claim 2, wherein the display module further comprises a shielding portion located on a side of the display function portion which is away from the bonding portion;
wherein an orthographic projection of the gap portion on the display function portion is located within the orthographic projection of the shielding portion on the display function portion.

4. The display module according to claim 2, wherein the gap portion is located in the first frame region.

5. The display module according to claim 1, wherein the display module comprises a first adhesive layer disposed at a side of the display function portion which is adjacent to the bonding portion, a first backplane layer disposed at a side of the first adhesive layer which is away from the display function portion, a second adhesive layer disposed at a side of the first backplane layer which is away from the display function portion, a light-shielding buffer layer disposed at a side of the second adhesive layer which is away from the display function portion, a third adhesive layer disposed at a side of the light-shielding buffer layer which is away from the display function portion, and a support function layer disposed at a side of the third adhesive layer which is away from the display function portion;
wherein the elastic modulus of the first sub-portion of the first adhesive layer is greater than the elastic modulus of the first sub-portion of the second adhesive layer, and the elastic modulus of the first sub-portion of the second adhesive layer is greater than the elastic modulus of the first sub-portion of the third adhesive layer.

6. The display module according to claim 5, wherein a thickness of the first sub-portion of the first adhesive layer is greater than a thickness of the first sub-portion of the second adhesive layer, and a thickness of the first sub-portion of the second adhesive layer is greater than a thickness of the first sub-portion of the third adhesive layer;
a sum of the thickness of the first sub-portion of the first adhesive layer, the thickness of the first sub-portion of the second adhesive layer, and the thickness of the first sub-portion of the third adhesive layer is equal to a sum of a thickness of the second sub-portion of the first adhesive layer, a thickness of the second sub-portion of the second adhesive layer, and a thickness of the second sub-portion of the third adhesive layer.

7. The display module according to claim 5, wherein the first sub-portion of the first adhesive layer comprises a first end portion away from the display region, and the first end portion protrudes from a corresponding end portion of the first backplane layer;
an orthographic projection of the first sub-portion of the second adhesive layer on the first backplane layer is located within the first backplane layer, and an orthographic projection of the first sub-portion of the second adhesive layer on the light-shielding buffer layer is located within the light-shielding buffer layer;
an orthographic projection of the first sub-portion of the third adhesive layer on the light-shielding buffer layer is located within the light-shielding buffer layer, and an orthographic projection of the first sub-portion of the second adhesive layer on the support functional layer is located within the support functional layer.

8. The display module according to claim 5, wherein the first adhesive layer is provided with a first gap sub-portion between the first sub-portion and the second sub-portion of the first adhesive layer, the second adhesive layer is provided with a second gap sub-portion between the first sub-portion and the second sub-portion of the second adhesive layer, and the third adhesive layer is provided with a third gap sub-portion between the first sub-portion and the second sub-portion of the third adhesive layer;
wherein a width of the first gap sub-portion is greater than or equal to a width of the second gap sub-portion, and a width of the second gap sub-portion is greater than or equal to a width of the third gap sub-portion.

9. The display module according to claim 8, wherein an orthographic projection of the first gap sub-portion on the display function portion, an orthographic projection of the second gap sub-portion on the display function portion, and an orthographic projection of the third gap sub-portion on the display function portion are overlapped.

10. The display module according to claim 5, wherein a bending radius of the first adhesive layer is less than a bending radius of the second adhesive layer, and a bending radius of the second adhesive layer is less than a bending radius of the third adhesive layer.

11. The display module according to claim 2, wherein the display module further comprises a polarizing layer located on a side of the display function portion which is away from the bonding portion;
wherein the polarizing layer is located within the display region and the first frame region, and an orthographic projection of the polarizing layer on the display function portion overlaps with an orthographic projection of the first sub-portion of the at least one adhesive layer on the display function portion.

12. The display module according to claim 11, wherein the display module further comprises a protective layer on a side of the bending portion which is away from the display region, and on a side of the display function portion which is away from the bonding portion;
wherein an end portion of the protective layer which is adjacent to one side of the polarizing layer is provided in the first frame region, and the protective layer and the polarizing layer are provided at an interval.

13. The display module according to claim 11, wherein the display module further comprises an ultra-thin glass on a side of the polarizing layer which is away from the display function portion, and a window cover plate on a side of the ultra-thin glass which is away from the display function portion.

14. The display module according to claim 13, wherein a width of the gap portion of the at least one adhesive layer is a first width in a direction from the bending portion to a center of the display function portion;
a thickness between a surface of a side, which is away from the window cover plate, of the support function layer and a surface of a side, which is away from the support function layer, of the window cover plate is a first thickness;
wherein the first width is 50% to 150% of the first thickness.

15. The display module according to claim 1, wherein the elastic modulus of the first sub-portion is greater than or equal to 20 Mpa.

16. The display module according to claim 1, wherein a material of the first sub-portion is a pressure-sensitive adhesive and a material of the second sub-portion is an optical adhesive.

17. A display device comprising a display module and a main body, the display module being integrated with the main body;
the display module comprising:
a display panel comprising a display function portion, a bonding portion disposed opposite to the display function portion, and a bending portion connecting the display function portion and the bonding portion;
at least one adhesive layer disposed on a side of the display function portion which is adjacent to the bonding portion;
wherein the display module comprises a display region corresponding to the display function portion and a first frame region located between the display region and the bending portion, the at least one adhesive layer comprises a first sub-portion and a second sub-portion, the first sub-portion is located in the first frame region, the second sub-portion is located in the display region and the first frame region, and the first sub-portion has an elastic modulus greater than the second sub-portion.

18. The display module according to claim 17, wherein the first sub-portion and the second sub-portion are provided separately, and the at least one adhesive layer is provided with a gap portion between the first sub-portion and the second sub-portion.

19. The display module according to claim 17, wherein the display module includes a first adhesive layer disposed on a side of the display function portion which is adjacent to the bonding portion, a first backplane layer disposed on a side of the first adhesive layer which is away from the display function portion, a second adhesive layer disposed on a side of the first backplane layer which is away from the display function portion, a light-shielding buffer layer disposed on a side of the second adhesive layer which is away from the display function portion, a third adhesive layer disposed on a side of the light-shielding buffer layer which is away from the display function portion, and a support function layer disposed at a side of the third adhesive layer which is away from the display function portion;
wherein the elastic modulus of the first sub-portion of the first adhesive layer is greater than the elastic modulus of the first sub-portion of the second adhesive layer, and the elastic modulus of the first sub-portion of the second adhesive layer is greater than the elastic modulus of the first sub-portion of the third adhesive layer.

20. The display module according to claim 17, wherein the display module further comprises a polarizing layer located on a side of the display function portion which is away from the bonding portion;
wherein the polarizing layer is located within the display region and the first frame region, and an orthographic projection of the polarizing layer on the display function portion overlaps with an orthographic projection of the first sub-portion of the at least one adhesive layer on the display function portion.
